(19) United States
(12) Patent Application Publication
(10) Pub. No.: US 2014/0332064 A1
(43) Pub. Date: Nov. 13, 2014

(54) SOLAR CELL MODULE

(71) Applicant: LG INNOTEK CO., LTD., Seoul (KR)

(72) Inventor: Chi Hong Park, Seoul (KR)

(21) Appl. No.: 14/366,557

(22) PCT Filed: Dec. 14, 2012
(86) PCT No.: PCT/KR2012/010964

§ 371 Date: Jun. 18, 2014

(30) Foreign Application Priority Data
Dec. 18, 2011 (KR) 10-2011-0136921

(51) Int. Cl. H01L 31/048; H01L 31/02

(52) U.S. Cl. CPC H01L 31/0485; H01L 31/02021
USPC 136/251; 136/244

(57) ABSTRACT

Disclosed is a solar cell module including a junction box, a cable connected with the junction box, and a diode having one end electrically connected to the junction box and an opposite end making contact with a PCS.

### TECHNICAL FIELD

The embodiment relates to a solar cell module.

### BACKGROUND ART

The photovoltaic power generation refers to a power generation scheme to convert the sunlight into electricity, and the core technology of the photovoltaic power generation is in a solar cell. Solar cells are manufactured in a series-connection structure/parallel-connection structure, if necessity, to endure the natural environment and the external shock for a long time. The minimum unit of the solar cells is called solar cell module. In addition, solar cell modules are installed in the structure of an array according to an actually used load.

In this case, most solar cell modules employ solar cell panels in which a plurality of solar cells are integrated. The solar cell panels are employed by combining several solar cells in the required capacity through the series-connection or parallel-connection of the solar cells. In addition, since most solar cell panels are manufactured by combining several solar cells according to a preset assembling process suitable for the requirement of an orderer, the assembled solar cell panel may not be partially replaced and exchanged in the failure of the solar cells.

In addition, the life spans of all solar cells constituting the solar cell panel are not the same. Accordingly, when each solar cell is failed, the power generation efficiency of the whole solar cell panel or the power generation efficiency of a solar cell set including the failed solar cell may be significantly degraded. In addition, the heat radiation of the failed solar cell causes the secondary failure of the whole solar cell panel.

The solar cell (or a photovoltaic cell) is a kind of a semiconductor device to directly convert the sunlight into electrical energy when the solar cell is exposed to the sunlight. Recently, the term photovoltaic cell is more frequently used rather than the term solar cell.

The photovoltaic (PV) power generation refers to a power generations scheme to directly convert the infinite and pollution-free solar energy into electrical energy. According to the PV power generation, a solar cell, a solar cell module, a solar cell panel, a solar cell array, a power conditioning system (PCS), and a battery are constructed.

A PV system includes a part to receive light and convert the light into electricity and a PCS to convert the produced electricity into AC current suitable for the demand of a user and to apply the AC current to a system.

In this case, the minimum unit of the solar cell is a cell. In general, since one cell produces the very small quantity of voltage corresponding to about 0.5V, a photovoltaic power generator, which is manufactured in the form of one package by connecting a plurality of solar cells to each other in series and in parallel, is used so that the voltage and the power representing a practical range can be obtained according to the use range of the solar cell.

### DISCLOSURE OF INVENTION

### Technical Problem

The embodiment provides a solar cell module having a simple circuit configuration by connecting a detachable diode to a connector connected to a PCS without providing an additional junction box.

### Solution to Problem

According to the embodiment, the solar cell module includes a junction box, a cable connected with the junction box, and a diode having one end electrically connected to the junction box and an opposite end making contact with a PCS.

### Advantageous Effects of Invention

As described above, according to the embodiment, the solar cell module has a simple circuit configuration by connecting the detachable diode to the connector connected to the PCS without providing the additional junction box.

### BRIEF DESCRIPTION OF DRAWINGS

FIG. 1 is a view showing the array of a solar cell module according to the related art;

FIG. 2 is an exploded perspective view showing the solar cell module according to the embodiment; and

FIG. 3 is a view showing the array of the solar cell module according to the embodiment.

### BEST MODE FOR CARRYING OUT THE INVENTION

In the description of the embodiments, it will be understood that, when a panel, a bar, a frame, a substrate, a groove, or a film is referred to as being on or under another panel, another bar, another frame, another substrate, another groove, or another film, it can be directly or indirectly on the other panel, the other bar, the other frame, the other substrate, the other groove, or the other film, or one or more intervening layers may also be present. Such a position of each component has been described with reference to the drawings. The size of each component shown in the drawings may be exaggerated for the purpose of convenience or clarity. In addition, the size of each component does not utterly reflect an actual size.

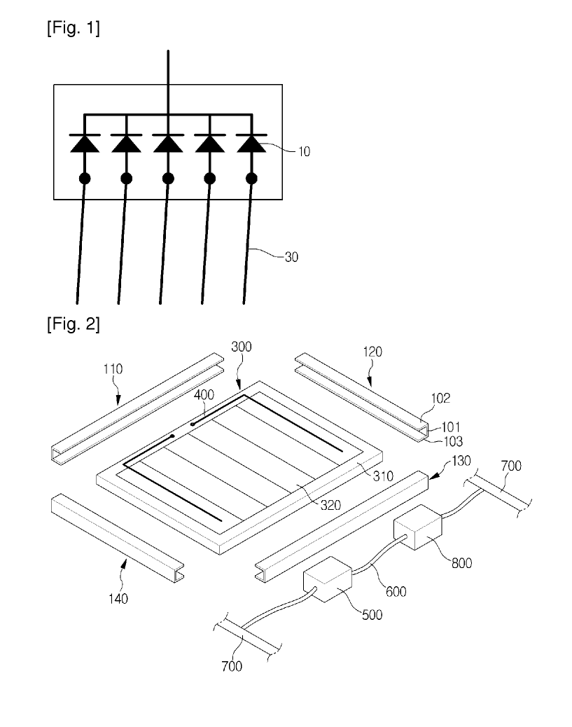

FIG. 1 is a view showing the array of a solar cell module according to the related art. As shown in FIG. 1, a cable 30 has one end connected to the solar cell module and an opposite end connected to a diode 10. A plurality of solar cell modules may be connected to each other in series. When series-connected modules are connected to each other in parallel like the parallel-connected cables 30, a reverse current blocking diode is attached before each group of the series-connected modules in order to prevent reverse current to be applied to the group. When a system is constructed by connecting the modules to each other in parallel using a low voltage PCS, since the reverse current blocking diode must be connected to each module output terminal, the circuit configuration may be very complicated.

FIG. 2 is an exploded perspective view showing a solar cell module according to the embodiment. Referring to FIG. 2, the solar cell module according to the embodiment includes a solar cell panel 300, a frame 100 to receive the solar cell panel 300, a fixing part 200 making contact with the frame 100 to fix the solar cell panel 300, a bus bar 400, a junction box 500, a cable 600, and a diode 800.

The frame 100 receives the solar cell panel 300. In more detail, the frame 100 surrounds the lateral sides of the solar cell panel 300. For example, the frame 100 is provided at four lateral sides of the solar cell panel 300.

The material that may constitute the frame 100 may include metal such as aluminum (Al). The frame 100 includes a first sub-frame 110, a second sub-frame 120, a third sub-frame 130, and a fourth sub-frame 140. The first sub-frame 110, the second sub-frame 120, the third sub-frame 130, and the fourth sub-frame 140 may be coupled with each other.

The first sub-frame 110 surrounds one lateral side of the solar cell panel 300. The second sub-frame 120 receives another lateral side of the solar cell panel 300. The third sub-frame 130 faces the first sub-frame 110 while interposing the solar cell panel 300 between the third and first sub-frames 130 and 110. The third sub-frame 130 receives another lateral side of the solar cell panel 300. The fourth sub-frame 140 receives still another frame of the solar cell panel 300. The fourth sub-frame 140 faces the second sub-frame 120 while interposing the solar cell panel 300 between the fourth sub-frame 140 and the second sub-frame 120.

The first, second, third, and fourth sub-frames 110, 120, 130, and 140 have structures similar to each other. In other words, each frame includes a support part to receive the solar cell panel 300.

For example, the first to fourth sub-frames includes first to third support parts 121 to 123.

The first support part 121 is provided at the lateral side of the solar cell panel 300. The first support part 121 supports the lateral side of the solar cell panel 300.

The second support part 122 extends from the first support part 121 so that the second support part 122 is provided on the top surface of the solar cell panel 300. The second support part 122 supports the top surface of the solar cell panel 300. The third support part 123 extends from the first support part 121 so that the third support part 123 is provided on the bottom surface of the solar cell panel 300. The third support part 123 supports the bottom surface of the solar cell panel 300. Although not shown, a fourth support part may be additionally provided, in which the fourth support part extends downward from the first support part 121 so that the fourth support part is provided under the third support part 123. The first support part 121, the second support part 122, and the third support part 123 may be integrally formed with each other.

The solar cell panel 300 may have a plate shape. For example, the solar cell panel 300 may have the shape of a rectangular plate. The solar cell panel 300 is provided inside the frame 100. In more detail, the outer portion of the solar cell panel 300 is provided inside the frame 100. In other words, four lateral sides of the solar cell panel 300 are provided inside the frame 100. The solar cell panel 300 receives the sunlight and converts the sunlight into electrical energy. The solar cell panel 300 includes a support substrate 310 and a plurality of solar cells 320.

In addition, the solar cell module according to the embodiment includes protective glass and an ethylene vinyl acetate (EVA) film.

The protective glass is provided on the solar cells 320. The protective glass protects the solar cells 320 from external physical shock and/or foreign matters. The protective glass is transparent. For example, the protective glass may include tempered glass.

The EVA film is interposed between the protective glass and the solar cells 320. The EVA film performs a buffer function between the protective glass and the solar cells 320.

The bus bar 400 is connected to the solar cell panel 300. In more detail, the bus bar 400 is provided on the top surfaces of the outermost solar cells 320. The bus bar 400 directly makes contact with the top surface of the outermost solar cells 320 so that the bus bar 400 is connected to the solar cells 320.

A hole is formed in a portion of the support substrate 310, so that the bus bar 400 may be connected to the cable 600 through the hole.

The junction box 500 is provided under the solar cell panel 300. The junction box 500 may be attached to the bottom surface of the solar cell panel 300. The junction box 500 may receive a circuit board connected to the bus bar 400 and the cable 600.

In addition, the solar cell module according to the embodiment may further a wire to connect the bus bar 400 to the circuit board. The cable 600 is connected to the circuit board and connected to another solar cell panel 300.

The diode 800 may be connected to the cable 600. The diode 800 may have one end connected to the cable 600, and an opposite end connected to the PCS 700. In detail, the anode of the diode 800 may be connected to the junction box 500 through the cable 600, and the cathode of the diode 800 may be connected to the PCS 700. A plurality of diodes 800 may be connected to each other in series.

In general, regarding the connection scheme of the solar cells constituting the solar cell panel, the parallel-structure has great current applied thereto, so that the thickness of a wire is increased, and an additional wire is required. Accordingly, the parallel-connection structure has an advantage in the insulating property between the solar cells and the insulating property of the wire.

In order to remove the failure caused by the current in the parallel-connection structure, a forward diode may be applied. Therefore, according to the embodiment of the present invention, a diode 800 having one end connected with the junction box 500 through the cable 600 and an opposite end connected to the PCS 700 may be provided to solve the failure caused by the current. The current can be prevented from being introduced into the junction box 500 from the PCS 700 through the diode 800.

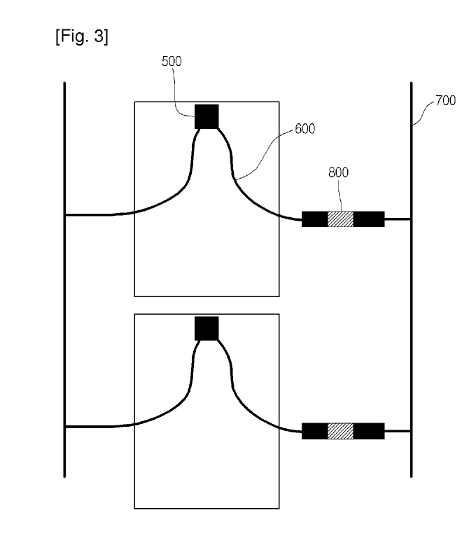

FIG. 3 is a view showing the array of the solar cell module according to the embodiment. As shown in FIG. 3, when the solar cell modules are connected to each other in parallel, the solar cell modules may be connected to each other through the diode 800. When the solar cell modules are connected to each other in series, the diode 800 may be detached. To this end, the diode 800 may be detachably installed. The diode 800 may include a detaching part that is detachable with respect to the cable 600. A positive electrode of the cable 600 may be connected to the anode of the diode 800.

Any reference in this specification to one embodiment, an embodiment, example embodiment, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell module comprising:
a junction box;
a cable connected with the junction box; and
a diode having one end connected to the junction box and an opposite end connected to a PCS.

2. The solar cell module of claim 1, wherein the diode has an anode connected to the junction box and a cathode connected to the PCS.

3. The solar cell module of claim 1, wherein a plurality of diodes are connected to each other in series.

4. The solar cell module of claim 1, wherein the diode includes a detaching part that is detachable with respect to the cable.

5. The solar cell module of claim 1, wherein the cable has a positive electrode connected to an anode of the diode.

6. The solar cell module of claim 1, further comprising:
a solar cell panel;
a frame to receive the solar cell panel; and
a fixing part making contact with the frame to fix the solar cell panel.

7. The solar cell module of claim 6, wherein the frame has a receiving part to receive the solar cell panel

8. The solar cell module of claim 7, wherein the solar cell panel includes a support substrate, and
a plurality of solar cells on the support substrate.

9. The solar cell module of claim 8, wherein the solar cell panel further includes a protective glass to cover the solar cells.

10. The solar cell module of claim 8, wherein the solar cell panel further includes an ethylene vinyl acetate (EVA) film interposed between the solar cells and the protective glass.

11. The solar cell module of claim 8, wherein the bus bar is provided on a top surface of an outermost solar cell.
